(19) United States
(12) Patent Application Publication
(10) Pub. No.: US 2006/0207457 A1
(43) Pub. Date: Sep. 21, 2006

(54) Method for controlling quality in a gravure-printed layer of an electroactive device

(75) Inventors: Svetlana Rogojevic, Niskayuna, NY (US); Anil Raj Duggal, Niskayuna, NY (US); Donald Franklin Foust, Scotia, NY (US); Dennis Joseph Coyle, Clifton Park, NY (US); Tami Janene Faircloth, Powell, WY (US); Larry Gene Turner, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/084,593

(22) Filed: Mar. 18, 2005

(51) Int. Cl. B41N 1/00

(52) U.S. Cl. 101/454

(57) ABSTRACT

Disclosed are methods for controlling quality in forward gravure printed electroactive layers for electroactive devices. The corresponding electroactive layers made by said methods and electroactive devices comprising said layers are also embodiments of the invention.

### STATEMENT REGARDING FEDERALLY SPONSORED RESEARCH & DEVELOPMENT

This invention was made with Government support under contract number 70NANB3H3030 awarded by NIST. The Government has certain rights in the invention.

### BACKGROUND OF THE INVENTION

The invention relates generally to a method for controlling quality in a gravure printed electroactive layer in an electroactive device, and particularly in an organic electroactive layer manufactured using gravure printing. Organic electroactive devices (OED), such as organic light-emitting diodes (OLEDs), could enable large energy savings when used for general illumination, due to their potentially higher efficiency than incandescent and fluorescent lights. However, for this potential to be realized their manufacturing process must be relatively cheap. Commercially viable manufacturing processes for organic electroactive devices must be relatively inexpensive and the quality of the devices fabricated, high. Currently, organic electroactive devices are manufactured using expensive microelectronics processing steps, such as spin-coating and vacuum deposition. It is understood that a real break-through in organic electroactive devices will come with roll-to-roll manufacturing using thin flexible plastic substrates. One of the key parameters determining the performance and reliability of the OED is the quality of the organic layers. An OED can have more than one organic layer. Organic layers can be used for such functions as charge transport (hole or electron transport layer), light-emitting or light-absorbing charge generating. The organic charge transport and light-emitting or light absorbing charge generating layers desirably need to be very thin, and their thickness uniformity should be excellent with the standard deviation in thickness desirably 5% or less. The layers should also be free of defects such as voids (pin holes) and particles that can cause shorts. Even though OEDs do not necessarily require a layer to be patterned in any fashion, it is typically the case that an organic layer will, in practice, be patterned in order to enable the creation of electrical contacts to a bottom electrode, or to enable more effective edge seal, or for other advantages.

Gravure is a printing process in which typically an ink or polymer solution is directly transferred from engraved cells mounted on an application roller to a substrate, typically without substantial differential speed between the substrate and the application roller. This typical mode of operation is also known as direct forward gravure. The gravure printing process typically includes but is not limited to the steps of wetting the engraved plate, filling up of cells with ink, removing excess ink using a doctor-blade, transferring the ink to a substrate, spreading of ink on the substrate, dewetting of ink from the substrate, leveling of coating, drying of film and solidification. Each of these steps is complex and is typically subject to defect introduction.

European patent application EP0986112 describes a gravure printing method for fabricating an OED such as an electroluminescent (EL) device. While the reference discusses gravure printing of various layers in an electroluminescent device, it does not discuss problems related to polymer uniformity and to defects such as pinholes, which may reduce the efficiency of the device. The reference does not describe methods to control the uniformity and defects in a gravure printed layer.

U.S. published patent application 20030089252 describes a gravure printing method for printing a pixelated array of an electrical device. The reference does not describe a continuous coating by gravure printing on a surface and further does not provide a method for controlling defects in such a gravure printed layer. U.S. published patent application 20040175550 describes a method for printing electrical circuits, such as used in radio frequency identification (RFID) tags, using gravure printing. But this reference again does not provide a method for controlling defects during gravure printing.

Therefore, there is a need for a process of printing very thin, uniform and defect-free electroactive layers, especially organic layers. It would be desirable to find a cost-effective method for roll-to-roll processing of such layers on large areas for the development of organic light-emitting diode (OLED) technology. In particular, when applied to a multi-element device with series electrical interconnections between elements, a method that provides cost advantage and simplicity of manufacturing over existing methods is highly desirable. Therefore, there is a need for a low-cost, fast, roll-to-roll compatible thin film deposition and patterning method, comprising high quality electroactive layers resulting in cheap, high-efficiency large-area organic electroactive devices.

### BRIEF DESCRIPTION OF THE INVENTION

In one embodiment the present invention is a method for controlling quality in at least one forward gravure printed organic electroactive layer, comprising the steps of: (i) preparing an aqueous solution or dispersion of an organic electroactive layer material in a mixture comprising a water miscible organic solvent; wherein the concentration of the solvent is in the range of from about 10% to about 60% by volume based on the total volume of the solution or dispersion, and the material solids level is in the range of from about 0.8% to about 3.5%; and (ii) depositing the solution or dispersion onto a substrate from a plurality of adjacent cells in an engraved gravure plate to form a continuous film of thickness less than about 200 nm and with a thickness variation of less than about 15%.

In another embodiment the present invention is a method for controlling quality in at least one forward gravure printed organic electroactive layer, comprising the steps of: (i) preparing a solution or dispersion of at least one organic electroactive layer material in a mixture comprising at least one low boiling point organic solvent with boiling point less than about 175° C. and at least one high boiling point organic solvent with boiling point greater than or equal to about 180° C.; wherein the concentration of the low boiling point solvent is in the range of from about 15% to about 85% by volume based on the total volume of the solution or dispersion; and (ii) depositing the solution or dispersion onto a substrate from a plurality of adjacent cells in an engraved gravure plate to form a continuous film of thickness less than about 200 nm, and with a thickness variation of less than about 15%.

The corresponding electroactive layers made by said methods and electroactive devices comprising said layers are also embodiments of the invention. Various other features, embodiments, and advantages of the present invention will become more apparent with reference to the following description and appended claims.

### BRIEF DESCRIPTION OF THE DRAWINGS

FIG. 1 is a schematic illustration of a gravure printing method in accordance with one embodiment of the present invention.

FIG. 2 is a graphical representation of the quality of a gravure printed film of an organic charge transport layer as a function of the percentage of organic solvent, the solids level, and the layer thickness in accordance with one embodiment of the present invention.

FIG. 3 is a graphical representation of the quality of a gravure printed film of an organic light emitting layer as a function of the percentage of high boiling solvent and the ratio of the two high boiling solvents employed in the ink mixture in accordance with one embodiment of the present invention.

FIG. 4 is a graphical representation of an electroactive device in accordance with one embodiment of the present invention.

### DETAILED DESCRIPTION OF THE INVENTION

In the following specification and the claims which follow, reference will be made to a number of terms which shall be defined to have the following meanings. The singular forms “a”, “an” and “the” include plural referents unless the context clearly dictates otherwise. The term “electroactive” as used herein refers to a material that is (1) capable of transporting, blocking or storing charge (either plus charge or minus charge), (2) luminescent, typically although not necessarily fluorescent, and/or (3) useful in photo-induced charge generation. An “electroactive device” is a device comprising an electroactive material. In the present context an electroactive layer is a layer for an electroactive device which comprises at least one organic electroactive material or at least one metal electrode material. As used herein the term “polymer” may refer to either homopolymers derived from essentially a single monomer or to copolymers derived from at least two monomers, or to both homopolymers and copolymers. As used herein, the term “registered” refers to positioning and alignment of one or more layers, and in particular embodiments means that two printed layers have identical patterns and that they are printed exactly on top of each other, so that the edges of the two identical patterns fall on top of each other. “Not registered” means that the printing of two layers is controlled so that the pattern edges of the two layers do not fall on top of each other.

In various embodiments the present invention is directed to methods for controlling the quality of organic electroactive layers in OEDs. One embodiment of the present invention is a method for printing a substantially thin, substantially uniform and substantially defect free electroactive layer using gravure printing. In one particular embodiment forward gravure printing is employed. Substantially thin means that the layer thickness is in one embodiment less than about 200 nanometers (nm) and in another embodiment less than about 100 nm. Uniformity may be determined by measuring the thickness variation of the electroactive layer. The thickness variation in one embodiment is less than about 15%, in another embodiment less than about 10%, in still another embodiment less than about 5%, and in still another embodiment less than about 2%. Any method known in the art may be used to determine thickness variation. For example, a spectrophotometer coupled with an optical illuminator may be used to measure the average thickness of electroactive layers, such as light emissive layers, based on their UV absorption. Also, variable angle spectroscopic ellipsometry (VASE) may be used. Other thickness variation measurement methods which may be used comprise light interferometry, and mechanical or optical profilometry. Substantially defect free in the present context means that the layer is substantially free of foreign particles, pinholes, and other defects which may adversely affect the efficiency of the electroactive layer as measured by the overall efficiency of the electroactive device. The level of defects may be readily determined visually, spectrophotometrically, microscopically, calorimetrically, or by employing like methods. Visual inspection of thin films on highly reflective substrates can desirably detect small non-uniformities, which show up as variations in film color. Comparison of photographs showing contrast and color variation may be used for detection of both defects and thickness variation.

In a particular embodiment the present invention is directed to a method for controlling the quality of an organic electroactive layer in an OED which method comprises a step of preparing an aqueous solution or dispersion of organic electroactive layer material in a mixture comprising a water miscible organic solvent in order to provide proper ink formulation for use in gravure printing of a high quality electroactive layer. The concentration of the organic solvent is in one embodiment in the range of from about 10% to about 60% by volume, in another embodiment in the range of from about 20% to about 50% by volume, and in still another embodiment in the range of from about 25% to about 50% by volume based on the total volume of the solution or dispersion. The organic electroactive layer material is present in one embodiment at a solids level in the range of from about 0.8% to about 3.5%, in another embodiment at a solids level in the range of from about 0.8% to about 2.5%, and in another embodiment at a solids level in the range of from about 1.5% to about 2.5%, wherein solids level is defined as weight of solid component per volume of liquid in the mixture. Non-limiting examples of solvents used in combination with water for preparing charge transport layers comprise isopropanol, ethanol, methanol, butanol, isobutanol, pentanol, isopentanol, acetone, ethylmethylketone, ethylene glycol, glycerol, propylene glycol monomethyl ether, butyl cellosolve, propylene carbonate, nitromethane, or similar solvents, or combinations thereof. In a further embodiment of the invention the aqueous solution or dispersion comprising water miscible organic solvent and organic electroactive layer material is degassed before depositing.

In a still another embodiment of the present invention an organic electroactive layer for an OED is printed from a solution or dispersion of at least one organic electroactive layer material in a mixture comprising at least one low boiling point organic solvent with boiling point less than about 175° C. and at least one high boiling point organic solvent with boiling point greater than or equal to about 180° C. In a still further embodiment the concentration of the low boiling point solvent is in the range of from about 15% to about 85% volume by total volume of the solution or dispersion. In still a further embodiment the concentration of the low boiling point solvent is in the range of from about 20% to about 70% volume by total volume of the solution or dispersion. In a further embodiment two high boiling point organic solvents comprise the balance of the solution. When two high boiling point solvents are present, then the volume fraction of the lower boiling of the two solvents in relation to the other solvent is in the range of from about 0.01 to about 0.99 with respect to the total volume of the two high boiling point solvents. In some embodiments three or more solvents may be used. In some particular embodiments the concentration of organic electroactive material in the solvent mixture is in a range of between about 0.5% and about 5%. Non-limiting examples of suitable organic solvents comprise aromatic hydrocarbons, substituted aromatic hydrocarbons, toluene, p-xylene, o-xylene, m-xylene, anisole, methylanisole, chlorobenzene, o-dichlorobenzene, mesitylene, decalin, tetralin, methylnaphthalene, and like materials, and combinations thereof.

Non-limiting examples of organic electroactive layers comprise any organic electroactive materials known for use in electroactive devices. In particular embodiments illustrative examples of organic electroactive materials comprise charge transport layer materials comprising low-to-intermediate molecular weight (for example, less than about 200,000) organic molecules, poly(3,4-ethylenedioxythiophene) (PEDOT), polyaniline, poly (3,4-propylenedioxythiophene) (PProDOT), polystyrenesulfonate (PSS), polyvinylcarbazole (PVK), or like materials, or combinations thereof.

In other particular embodiments non-limiting examples of organic electroactive layer materials comprise organic light emitting layers comprising poly(N-vinylcarbazole) (PVK) and its derivatives; polyfluorene and its derivatives such as poly(alkylfluorene), for example poly(9,9-dihexylfluorene), poly(dioctylfluorene) or poly{9,9-bis(3,6-dioxaheptyl)-fluorene-2,7-diyl}, poly(para-phenylene) (PPP) and its derivatives such as poly(2-decyloxy-1,4-phenylene) or poly(2,5-diheptyl-1,4-phenylene); poly(p-phenylene vinylene) (PPV) and its derivatives such as dialkoxy-substituted PPV and cyano-substituted PPV; polythiophene and its derivatives such as poly(3-alkylthiophene), poly(4,4′-dialkyl-2,2′-bithiophene), poly(2,5-thienylene vinylene); poly(pyridine vinylene) and its derivatives; polyquinoxaline and its derivatives; and polyquinoline and its derivatives. In one particular embodiment a suitable light emitting material is poly(9,9-dioctylfluorenyl-2,7-diyl) end capped with N,N-bis(4-methylphenyl)-4-aniline. Mixtures of these polymers or copolymers based on one or more of these polymers and others may also be used.

Another class of suitable materials used in light emitting layers are polysilanes. Typically, polysilanes are linear silicon-backbone polymers substituted with a variety of alkyl and/or aryl side groups. They are quasi one-dimensional materials with delocalized sigma-conjugated electrons along polymer backbone chains. Examples of polysilanes comprise poly(di-n-butylsilane), poly(di-n-pentylsilane), poly(di-n-hexylsilane), poly(methylphenylsilane), and poly{bis(p-butylphenyl)silane}.

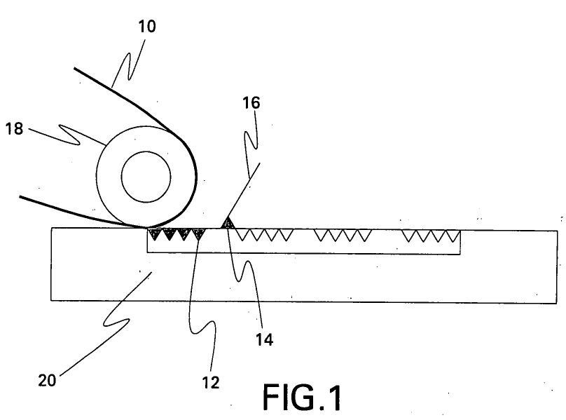

In various embodiments of the gravure printing process at least one doctor blade 16 spreads the solution or ink 14 on an engraved plate 20 and wipes the excess ink off the engraved plate in preparation for deposition to take place onto a substrate 10. In a particular embodiment an engraved application roller and a substrate 10 (backed-up by an impression roller) move in the same direction, typically at comparable speeds. In still another embodiment the engraved plate 20 is stationary and a doctor blade and an impression roller 18 move across the plate surface to enable printing as depicted in FIG. 1. Other configurations wherein a flexible substrate is used without a backing roller are also within the scope of the invention.

In the present invention gravure printing of a certain shaped and sized element or pixel is not achieved by printing from individual cells comparable in size to the desired element or pixel, but instead, the method comprises printing from multiple cells such that the deposited solution coalesces to form a single larger uniform element or pixel. The characteristics of the plurality of gravure cells in an engraved plate used for deposition may be suitably selected to print a film of a desired shape, size, thickness and uniformity. Such characteristics include, but are not limited to, cell volume, channel width, wall-width, and screen angle. The characteristics of the solution or dispersion may also be suitably selected to print a film of a desired shape, size, thickness and uniformity. Such characteristics include, but are not limited to, solids level, surface tension, viscosity, and volatility.

Cell volume and solids level in the printing ink are among the factors determining the final dry film thickness. In one embodiment the dry film thickness is approximately given by the equation (0.5×cell volume per surface area×solids level)/(density of dry film), where solids level is expressed as solids weight per solvent volume as noted earlier. In one example, to arrive at a target film thickness of 75 nm, a 7.5 micron volume plate (i.e. 7.5 cubic microns per square micron of plate area) may be used with solutions or dispersions comprising 2% solids, and a 15 micron volume plate may be used with solutions or dispersions comprising 1% solids (wherein dry film density is assumed to be approximately 1 gram per cubic centimeter).

In a further embodiment of the invention the choice of the drying method and the length of time for drying are determined by an estimated leveling rate. The deposited film may be slow dried at room temperature or fast dried through application of heat, for example, using a heat gun, continuous drying oven, heat lamp, or like methods. The choice of drying method and time depend upon such factors as solids concentration, solvent boiling point, surface area, and like factors, and may be readily determined without undue experimentation. Typically, the drying time is adjusted to exceed the time needed for film leveling. The dissipation of the sinusoidal disturbance in a deposited film by leveling can be described by the equation:

$$ln \frac{{a}_{0}}{{a}_{t}} = \frac{5.3 γ {x}^{3}}{{λ}^{4}} \cdot \frac{dt}{η}$$

where a₀ and aₜ are the disturbance amplitudes at times “0” and “t” respectively, γ (in units of milliNewtons per meter (mN/m) is surface tension, x (centimeters (cm)) is the average film thickness, λ (cm) is the wavelength of disturbance, t (seconds) is time, η (in units of pascal·seconds (Pa·s)) is fluid viscosity. In typical embodiments of the invention the wet film thickness is primarily determined by the engraving volume. The fluid parameters in the equation can vary with time. For example, viscosity increases with time as the wet film drys. Surface tension may stay constant but in the case of solvent mixtures it may also vary with time because the solvent composition changes with time during evaporation. However, surface tension, which is the driving force for leveling, can vary across all liquids at most by a factor of 3.4 (between 20 and 70 mN/m), and therefore does not affect the leveling rate greatly. The other factors, namely viscosity, wavelength of disturbance and drying rate and in particular those with high exponents, affect the leveling rate the most. The drying rate is implicit in the equation because it determines how the viscosity varies with time. As an example of a typical calculation of drying time as a function of estimated leveling rate the parameters of the equation may be set as follows: surface tension at 30 mN/m, viscosity at 0.02 Pa·s (and assuming the viscosity does not change with drying), average film thickness at 4 micometers, and wavelength of disturbance at 0.5 mm. With these parameter values the equation yields an estimated drying time of 28 seconds in order to dissipate 90% of the disturbance (a₀/aₜ=10).

In other embodiments at least two organic electroactive layers in an OED are prepared by a method of the present invention. In still another embodiment one or more organic electroactive layers are printed in a predetermined pattern on a substrate. In a further embodiment at least two organic electroactive layers are printed with different predetermined patterns. In a further embodiment at least two organic electroactive layers are printed with the same pattern and are registered with respect to each other. In another embodiment at least two organic electroactive layers are printed with the same pattern and are not registered with respect to each other.

In another embodiment of the invention patterning of the organic electroactive layer is imparted during depositing to the substrate. In another embodiment patterning is imparted following material deposition In a further embodiment patterning is enabled by suitable preparation of the substrate prior to the material deposition onto the substrate.

Still another embodiment of the present invention is an organic electroactive layer made by a method of the present invention. Non-limiting examples of organic electroactive layers comprise any organic electroactive materials known for use in electroactive devices. In a particular embodiment the organic electroactive layer is a light emitting polymer layer. In still another particular embodiment the organic electroactive layer is a charge transport layer.

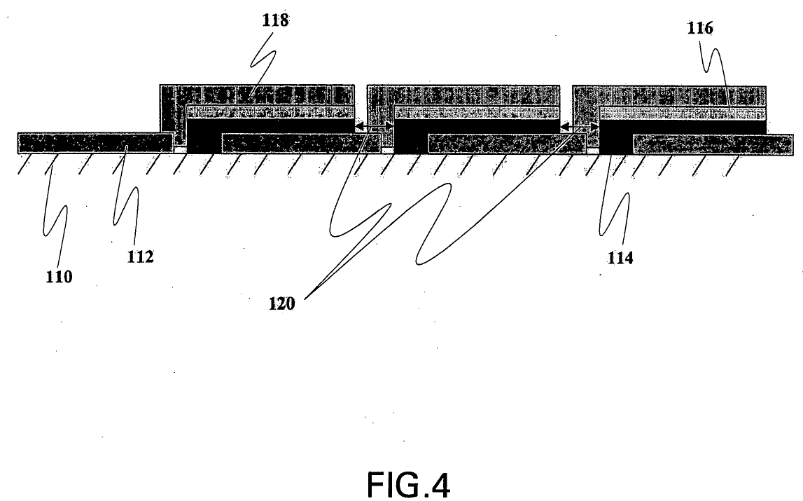

Another embodiment of the present invention is an electroactive device wherein at least one organic electroactive layer is made by a method described herein. Another embodiment of the invention is an electroactive device with series interconnected architecture, wherein at least one organic electroactive layer is made by the methods described herein. Series interconnected architecture is described in detail in U.S. published patent application 20040021425. An example of a device with series interconnected architecture is shown in FIG. 4. A further embodiment of this invention is an electroactive device comprising this layer, wherein said electroactive device is selected from the group consisting of a light emitting device, a photovoltaic device, a radio frequency identification tag (RFID), a printed thin-film transistor device, electronic backplane, integrated circuit, and combinations thereof. In a further embodiment of the present invention is an opto-electroactive device.

In one embodiment the electroactive device typically comprises: (a) an anode; (b) a cathode; and (c) a hole-blocking layer. In another embodiment the electroactive device typically comprises: (a) an anode; (b) a light-emitting layer; (c) a hole-blocking layer; and (d) a cathode. In another embodiment the electroactive device typically comprises: (a) an anode; (b) a light-emitting layer; (c) a hole-injecting or hole-transporting layer; and (d) a cathode. In a further embodiment the electroactive device often comprises: (i) a substrate; (ii) an anode formed over the substrate; (iii) a layer of a hole transporter material formed over the anode; (iv) optionally an electron-blocking layer; (v) a layer of light-emitting material; (vi) a layer of a hole-blocking material (vii) a layer of an electron transporter material; and (viii) a cathode formed over the layer of electron transporter material. In still a further embodiment the electroactive device typically comprises: (a) an anode; (b) a cathode; and (c) a layer of light-emitting material. In some other embodiments the electroactive device often comprises: (a) a substrate; (b) an anode formed over the substrate; (c) optionally a layer of a hole transporter material formed over the anode; (d) optionally an electron-blocking layer; (f) a layer of light-emitting material (g) optionally a layer comprising a hole-blocking material; (h) optionally a layer comprising an electron transporter material; and (i) a cathode. In still another embodiment the electroactive device typically comprises: (a) an anode; (b) a cathode and (c) a layer of light-absorbing charge-generating material. Electroactive devices of the present invention may comprise additional layers such as, but not limited to, one or more of an abrasion resistant layer, a chemically resistant layer, a photoluminescent layer, a radiation-absorbing layer, a radiation reflective layer, a barrier layer, a planarizing layer, optical diffusing layer, and combinations thereof.

Non-limiting examples of hole injection enhancement layer materials comprise organic electroactive materials such as, but not limited to, arylene-based compounds such as 3,4,9,10-perylenetetra-carboxylic dianhydride, bis(1,2,5-thiadiazolo)-p-quinobis(1,3-dithiole), and like materials.

Non-limiting examples of hole transport layer materials comprise organic electroactive materials such as, but not limited to, triaryldiamine, tetraphenyldiamine, aromatic tertiary amines, hydrazone derivatives, carbazole derivatives, triazole derivatives, imidazole derivatives, oxadiazole derivatives having an amino group, polythiophenes, and like materials.

Materials suitable for the electron injection and transport enhancement materials comprise organic electroactive materials such as, but not limited to, metal organic complexes such as oxadiazole derivatives, perylene derivatives, pyridine derivatives, pyrimidine derivatives, quinoline derivatives, quinoxaline derivatives, diphenylquinone derivatives, nitro-substituted fluorene derivatives, and like materials.

Suitable materials for a hole blocking layer comprise organic electroactive materials such as, but not limited to, poly(N-vinyl carbazole), and like materials.

Suitable cathode material for electroactive devices typically comprise materials having low work function value. Non-limiting examples of cathode materials comprise materials such as K, Li, Na, Mg, Ca, Sr, Ba, Al, Ag, Au, In, Sn, Zn, Zr, Sc, Y, Mn, Pb, elements of the lanthanide series, alloys thereof, particularly Ag—Mg alloy, Al—Li alloy, In—Mg alloy, Al—Ca alloy, and Li—Al alloy and mixtures thereof. Other examples of cathode materials may comprise alkali metal fluorides, or alkaline earth fluorides, or mixtures of fluorides. Other cathode materials such as indium tin oxide, tin oxide, indium oxide, zinc oxide, indium zinc oxide, zinc indium tin oxide, antimony oxide, carbon nanotubes, and mixtures thereof are also suitable. Alternatively, the cathode can be made of two layers to enhance electron injection. Non-limiting examples include, but are not limited to, an inner layer of either LiF or NaF followed by an outer layer of aluminum or silver, or an inner layer of calcium followed by an outer layer of aluminum or silver.

Suitable anode materials for electroactive devices typically comprise those having a high work function value. Non-limiting examples of anode materials include, but are not limited to, indium tin oxide (ITO), tin oxide, indium oxide, zinc oxide, indium zinc oxide, nickel, gold, and like materials, and mixtures thereof.

Non-limiting examples of substrates which may be used are selected from the group consisting of a thermoplastic polymer, poly(ethylene terephthalate), poly(ethylene naphthalate), polyethersulfone, polycarbonate, polyimide, acrylate, polyolefin, glass, metal, and like materials, and combinations thereof.

In one embodiment the present invention is a large area organic light emitting device. In a further embodiment of the present invention at least one organic layer is patterned in order to enable the creation of electrical contacts to an electrode, or to enable more effective edge seal. Still a further embodiment is a gravure printing method of a fault-tolerant OLED device. The device continues functioning even if electrical shorts or opens affect some portions of it. In one embodiment the present invention is a gravure printing method enabling the gravure printing of electroactive layers to enable a fault-tolerant OLED. In one non-limiting example, the device incorporates a multitude of device elements, typically 1.6 sq cm in area, with series and parallel connections between them. In order to enable a series connection between two elements, a cathode of one element is connected to the anode of the next one, through a region free of polymer. In a non-limiting example the polymer free street of region (“polymer street”) is about 1.3 millimeters (mm) wide, with positioning accuracy of plus or minus 1.8 mm.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### COMPARATIVE EXAMPLE 1

A typical PEDOT film was made by gravure printing. A color photograph taken of this film shows that the 90 nm thick film exhibited significant non-uniformities with a predominantly grainy pattern and with some less pronounced streaking in the coating direction. The thickness variation across a 2.54 cm patch of film were estimated to be plus or minus 15 nm by a colorimetry method. The pattern resembled the pattern of the gravure cells in the engraved plate. However, the length scales of these patterns were different. The grain size of the PEDOT film was typically 3-5 times the size of an engraved cell used to produce the film. This may be attributed to a multiple cell pickout, which is quite common to gravure printing, whereby the fluid picked out from several neighboring cells collapses and forms a larger clump of fluid as it is transferred to the substrate.

### COMPARATIVE EXAMPLE 2

A typical PEDOT film was made by gravure printing using commercially available PEDOT:PSS dispersions which are completely water-based and have surface tension typically equal to that of water (70 dynes/cm). A color photograph taken of this film showed that the high surface tension is generally not suitable for uniform coating. The problem was particularly evident with patterned ITO/PET substrates, in which both ITO and PET surfaces were exposed to this ink. Even though the substrates were UV-ozone treated before printing in order to increase the surface energy and make them receptive to the ink, ITO and PET surfaces still have different affinities to water, which caused ink dewetting from ITO/PET edges, from the substrate edges, and from point defects in the film.

### COMPARATIVE EXAMPLE 3

A typical PEDOT film was made by gravure printing using commercially available PEDOT:PSS aqueous dispersions to which 20% by volume isopropanol was added. While the use of isopropanol eliminated pinholes and the uncoated ITO edges, typical coatings made using these new solutions resulted in different type of nonuniformity. A color photograph of the PEDOT layer showed pronounced streaks of varying thickness in the direction of coating. This problem was particularly aggravated on patterned ITO/PET substrates (as opposed to the unpatterned ones), and also resulted in poor run-to-run reproducibility of the coatings.

### COMPARATIVE EXAMPLE 4

A typical LEP film was made by gravure printing. Typical LEP solutions used for spin-coating utilize p-xylene (boiling point: 138° C.) as solvent. But for gravure printing, mesitylene (boiling point: 163° C.) was used instead because of the risk of xylene-based solutions drying too fast in the engraved portions of the printing plate before being cleaned up. A color photograph of the gravure printed LEP film shows a grainy type of nonuniformity.

### EXAMPLE 1

A commercially available gravure proofer, RK303, made by Print Coat Instruments, Ltd. was used for gravure printing. Flat plates with suitable electromechanical engraving were obtained from Armotek, and were fitted on the RK303 proofer. The cells were engraved using a diamond stylus with 120° tip angle, and allowing for channels between the cells, in order to promote film flow and leveling. Three engraving variables varied from patch to patch on each plate: screen angle (36 or 45 degrees), channel width (9-34 micrometers), and wall width (15-31 micrometers). Two other dependent variables that vary as a consequence are cell width and cell count (number of cells per cm, or lines per cm). In case of the low-volume engravings (7.5 cubic micron per square micron of plate area), typical cell width was 95 micrometers, with screen count of 118 lines per cm. In the case of the high-volume engravings (15 cubic micron per square micron of plate area), typical cell width was 175 micrometers with screen count of 67 lines per cm. Commercially available ITO coated PET substrate was obtained from Sheldahl and was used as the substrate in the printing process. The solution for printing a conductive PEDOT layer was prepared by blending of commercially available aqueous PEDOT (Baytron P VP CH 8000) with isopropanol, such that isopropanol comprised 33% of the total volume of the solution. The overall solids content was estimated to be about 1.75%. The solution was filtered through a 0.45 micron filter. The filtered solution was degassed by placing it in a vacuum chamber and exposing it to 80 kilopascals (kPa) vacuum for 3 minutes. The solution was spread over the plate by a doctor blade to fill every cell to the top. The PET substrate was UV-ozone treated for 10 minutes and attached to the roller of the RK303 proofer. The substrate was then brought into contact with the filled cells, and about 50% of the content of each cell was transferred to the substrate upon substrate release. Printing speed was 39 meters/minute. The PEDOT layer was dried using a heat gun for 3 minutes before subsequent layers were deposited. The thin film (50-150 nm thick) had an estimated uniformity of better than plus/minus 5 nm, and edge resolution better than 200 microns. On visual inspection it was determined to be pinhole-free and smooth with barely visible color variations, indicating uniform film thickness.

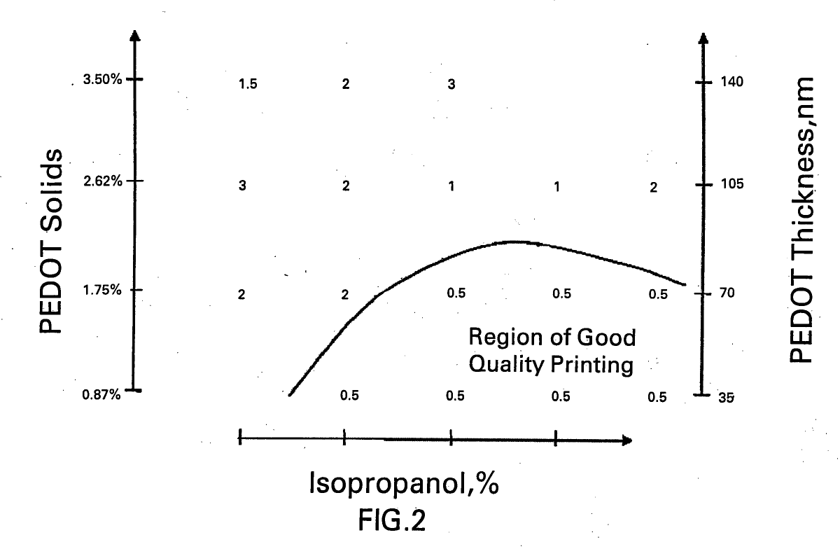

FIG. 2 shows the quality of a gravure printed film as a function of the percentage of isopropanol solvent, the PEDOT solids level, and PEDOT thickness wherein quality is a visual measure of both thickness uniformity and defect-free characteristic of the film. A quality rating number of “0”, indicates highest quality, while a rating number of “3” indicates lowest quality. A rating at or below “0.5” may be considered as indicative of a high quality film.

### EXAMPLE 2

A commercially available gravure proofer, RK303, made by Print Coat Instruments, Ltd. was used for gravure printing. A flat plate was electromechanically engraved using a diamond stylus with 120 degree tip angle at a density of 120 cells per centimeter with a cell width of 95 microns. Commercially available indium tin oxide (ITO) coated flexible transparent plastic substrate was obtained from (Sheldahl) and was used as the substrate in the printing process. A light-emitting polymer (LEP) solution of 2% concentration was prepared by dissolving American Dye Source 329 (ADS 329; poly(9,9-dioctylfluorenyl-2,7-diyl) end capped with N,N-bis(4-methylphenyl)-4-aniline) in a mixture consisting of 60% mesitylene (the low-boiling point solvent), 30% of decalin and 10% of tetralin (i.e. the decalin fraction was 0.75 in the high boiling point decalin/tetralin mixture). The solution was filtered through a 0.2 micron filter. The solution was spread over the engraved plate by a doctor blade to fill every cell to the top. The ITO coated flexible transparent plastic substrate was then brought into contact with the filled cells, and about 50% of content of each cell was transferred to the substrate upon substrate release. The layer was dried slowly before subsequent layers were deposited. On visual inspection it was determined to be pinhole-free and smooth with barely visible color variations, indicating uniform film thickness. The exceptional uniformity of the printed polymer layer has been confirmed by the fact that the light emission from the resulting device appears visually uniform without any significant intensity variation or color variation across the device.

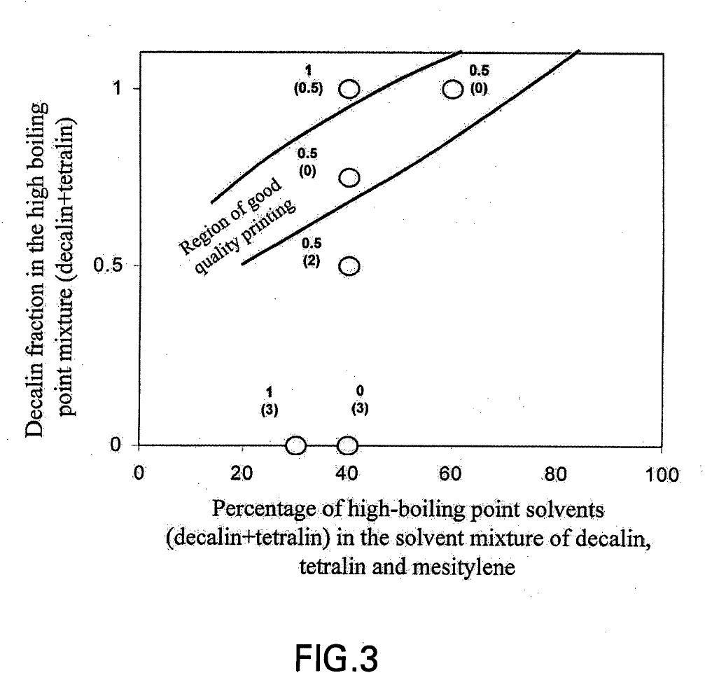

FIG. 3 shows the quality of the gravure printed film as a function of the percentage of high boiling solvent mixture and the ratio of the two high boiling solvents employed in the ink mixture. The numbers shown are the quality ratings for the film and polymer free street region (uncoated narrow area limited by two film edges). The upper number is the quality rating for film uniformity. The lower number in parenthesis is the quality rating for film edges. A quality rating number of “0” indicates no visible defects, i.e. perfect film or edge. A quality rating number of “3” indicates very bad film uniformity or edge. A quality rating at or below “0.5” means only some defects are barely visible. A rating of 0.5 or 0 is considered acceptable quality.

### EXAMPLE 3

For printing of 15.2 cm OLED devices, a flexible plastic substrate with suitably patterned ITO was used to enable the interconnected device architecture. A 0.18 mm PET substrate coated with ITO having 40 ohm/square sheet resistance was used (ACCENTIA™ obtained from Sheldahl). The ITO layer was patterned either by laser ablation or by a photoresist method. To selectively print the polymer layers on the substrate, the ITO pattern was aligned to the engraving on the plate by suitably placing the marks along and across the impression roller of the gravure coater and visually aligning the substrate edges to these marks. This enabled the polymer streets (uncoated areas) to be placed correctly with respect to the ITO pattern, within a plus or minus 1.8 mm tolerance zone. The substrate was subjected to UV-ozone pretreatment for 10 minutes, then the substrate was taped to the impression roller. A PEDOT solution was filtered through a 0.45 micron filter, and the PEDOT layer was printed, followed by fast-drying using a heat gun for about 3 minutes. An LEP solution (2.1% of ADS 329 dissolved in a mixture consisting of 60% mesitylene, 30% decalin and 10% tetralin) was filtered through a 0.2 micron filter, and LEP layer was printed, followed by slow drying at room temperature. A pre-cathode bake in a glove box under N₂ atmosphere at 110° C. for 10 minutes was followed by evaporative deposition of a 16 nm layer of NaF and was followed by evaporative deposition of 200 nm layer of Al. Cathode-side encapsulation was done by an Al foil with acrylic adhesive, conducted in the glove box under an N₂ atmosphere. One row of the device was evaluated at a constant current density of 10 mA/cm², and exhibited an efficiency of 1.1 Candela per ampere (Cd/A), comparable to similar spin-coated devices.

### EXAMPLE 4

For printing of OLED devices, a flexible plastic substrate with suitably patterned ITO is used to enable the interconnected device architecture. A high-temperature polycarbonate (LEXAN®) with suitably engineered coatings including the moisture/oxygen barrier and finished with an ITO layer, is used. The ITO layer is patterned either by laser ablation or by a photoresist method. To selectively print the polymer layers on the substrate, the ITO pattern is aligned to the engraving on the plate by suitably placing the marks along and across the impression roller of the gravure coater and visually aligning the substrate edges to these marks. This enables the polymer streets (uncoated areas) to be placed correctly with respect to the ITO pattern, within a desired tolerance zone. The substrate is subjected to UV-ozone pretreatment, then the substrate is taped to the impression roller. A PEDOT solution is filtered through a 0.45 micron filter, and the PEDOT layer is printed, followed by fast-drying using a heat gun for about 3 minutes. An LEP solution (2.1% of ADS 329 dissolved in a mixture consisting of 60% mesitylene, 30% decalin and 10% tetralin) is filtered through a 0.2 micron filter, and the LEP layer is printed, followed by slow drying at room temperature. A pre-cathode bake in a glove box under N₂ atmosphere is followed by evaporative deposition of a layer of NaF and is followed by evaporative deposition of a layer of Al. Cathode-side encapsulation is done by an Al foil with acrylic adhesive conducted in the glove box under an N₂ atmosphere. The device exhibits adequate performance characteristics. The brightness and light uniformity are comparable to spin-coated devices.

The previously described embodiments of the present invention have many advantages, including a high quality, low-cost, fast, roll-to-roll compatible thin film deposition and patterning method, resulting in cheap, high-efficiency large-area OED devices. While only certain features of the invention have been illustrated and described herein, many modifications and changes will occur to those skilled in the art. It is, therefore, to be understood that the appended claims are intended to cover all such modifications and changes as fall within the true spirit of the invention. All patents, published patent applications, and published articles cited herein are incorporated herein by reference.

1. A method for controlling quality in at least one forward gravure printed organic electroactive layer, comprising the steps of:
(i) preparing an aqueous solution or dispersion of an organic electroactive layer material in a mixture comprising a water miscible organic solvent; wherein the concentration of the solvent is in the range of from about 10% to about 60% by volume based on the total volume of the solution or dispersion, and the material solids level is in the range of from about 0.8% to about 3.5%; and
(ii) depositing the solution or dispersion onto a substrate from a plurality of adjacent cells in an engraved gravure plate to form a continuous film of thickness less than about 200 nm and with a thickness variation of less than about 15%.

2. The method of claim 1, wherein the electroactive layer is an organic charge transport layer.

3. The method of claim 2, wherein said organic charge transport layer material is selected from the group consisting of poly(3,4-ethylenedioxythiophene), poly(3,4-propylenedioxythiophene), polystyrenesulfonate, polyvinylcarbazole, oxadiazole derivatives, perylene derivatives, pyridine derivatives, pyrimidine derivatives, quinoline derivatives, quinoxaline derivatives, diphenylquinone derivatives, nitro-substituted fluorene derivatives, polyaniline, triaryldiamine, tetraphenyldiamine, aromatic tertiary amines, hydrazone derivatives, carbazole derivatives, triazole derivatives, imidazole derivatives, oxadiazole derivatives having an amino group, polythiophenes and combinations thereof.

4. The method of claim 1, further comprising the step of degassing said solution or dispersion before depositing.

5. The method of claim 1, further comprising the step of drying the deposited film for a length of time determined by an estimated leveling rate.

6. The method of claim 1, wherein the electroactive layer is printed in a pattern on said substrate.

7. The method of claim 1, wherein the electroactive layer and at least one additional electroactive layer are printed with different patterns.

8. The method of claim 1, wherein the electroactive layer and at least one additional electroactive layer are printed with the same pattern and are registered with respect to each other.

9. The method of claim 1, wherein the electroactive layer and at least one additional electroactive layer are printed with the same pattern and are not registered with respect to each other.

10. The method of claim 1, wherein the organic solvent is selected from the group consisting of isopropanol, ethanol, methanol, butanol, isobutanol, pentanol, isopentanol, acetone, ethylmethylketone, ethylene glycol, glycerol, propylene glycol monomethyl ether, butyl cellosolve, propylene carbonate, nitromethane, and combinations thereof.

11. The method of claim 1, wherein the substrate is selected from the group consisting of a thermoplastic polymer, poly(ethylene terephthalate), poly(ethylene naphthalate), polyethersulfone, polycarbonate, polyimide, acrylate, polyolefin, glass, metal, and combinations thereof.

12. The method of claim 1, wherein the substrate is a thermoplastic polymer sheet comprising an integrated moisture and oxygen barrier layer.

13. An organic electroactive layer prepared by the method of claim 1.

14. An electroactive device comprising at least one organic electroactive layer prepared by the method of claim 1.

15. The electroactive device of claim 14, wherein the electroactive layer is printed in a pattern on said substrate.

16. The electroactive device of claim 14, wherein the electroactive layer and at least one additional electroactive layer are printed with different patterns.

17. The electroactive device of claim 14, wherein the electroactive layer and at least one additional electroactive layer are printed with the same pattern and registered with respect to each other.

18. The electroactive device of claim 14, wherein the electroactive layer and at least one additional electroactive layer are printed with the same pattern and not registered with respect to each other.

19. The electroactive device of claim 14, having a series interconnected architecture.

20. The electroactive device of claim 14, which is an organic light emitting device.

21. The electroactive device of claim 14, which is an organic photovoltaic device.

22. A method for controlling quality in at least one forward gravure printed organic electroactive layer, comprising the steps of:
(i) preparing a solution or dispersion of at least one organic electroactive layer material in a mixture comprising at least one low boiling point organic solvent with boiling point less than about 175° C. and at least one high boiling point organic solvent with boiling point greater than or equal to about 180° C.; wherein the concentration of the low boiling point solvent is in the range of from about 15% to about 85% by volume based on the total volume of the solution or dispersion; and
(ii) depositing the solution or dispersion onto a substrate from a plurality of adjacent cells in an engraved gravure plate to form a continuous film of thickness less than about 200 nm, and with a thickness variation of less than about 15%.

23. The method of claim 22, wherein the electroactive layer is an organic light emitting layer.

24. The method of claim 23, wherein the organic light emitting material is selected from the group consisting of poly(N-vinylcarbazole), polyfluorene, poly(alkylfluorene), poly(para-phenylene), poly(p-phenylene vinylene), polythiophene, poly(pyridine vinylene), polyquinoxaline, polyquinoline, polysilanes, and combinations thereof.

25. The method of claim 22, wherein at least two high boiling point organic solvents are present, with the fraction of the solvent with the lowest boiling point of the two solvents being in the range of from about 0.01 to about 0.99 by volume.

26. The method of claim 22, further comprising the step of drying the deposited film for a length of time determined by an estimated leveling rate.

27. The method of claim 22, wherein the electroactive layer is printed in a pattern on said substrate.

28. The method of claim 22, wherein the electroactive layer and at least one additional electroactive layer are printed with different patterns.

29. The method of claim 22, wherein the electroactive layer and at least one additional electroactive layer are printed with the same pattern and are registered with respect to each other.

30. The method of claim 22, wherein the electroactive layer and at least one additional electroactive layer are printed with the same pattern and are not registered with respect to each other.

31. The method of claim 22, wherein the organic solvents are selected from the group consisting of aromatic hydrocarbons, substituted aromatic hydrocarbons, toluene, p-xylene, o-xylene, m-xylene, anisole, methylanisole, chlorobenzene, o-dichlorobenzene, mesitylene, decalin, tetralin, methylnaphthalene and combinations thereof.

32. The method of claim 22, wherein the substrate is selected from the group consisting of a thermoplastic polymer, poly(ethylene terephthalate), poly(ethylene naphthalate), polyethersulfone, polycarbonate, polyimide, acrylate, polyolefin, glass, metal, and combinations thereof.

33. The method of claim 22, wherein the substrate is a thermoplastic polymer sheet with an integrated moisture and oxygen barrier layer.

34. An organic electroactive layer prepared by the method of claim 22.

35. An electroactive device comprising at least one organic electroactive layer prepared by the method of claim 22.

36. The electroactive device of claim 35, wherein the electroactive layer is prepared in a pattern.

37. The electroactive device of claim 35, wherein the electroactive layer and at least one additional electroactive layer are printed with different patterns.

38. The electroactive device of claim 35, wherein the electroactive layer and at least one additional electroactive layer are printed with the same pattern and registered with respect to each other.

39. The electroactive device of claim 35, wherein the electroactive layer and at least one additional electroactive layer are printed with the same pattern and not registered with respect to each other.

40. The electroactive device of claim 35, having a series interconnected architecture.

41. The electroactive device of claim 35, which is an organic light emitting device.

42. The electroactive device of claim 35, which is an organic photovoltaic device.
